(19) United States
(12) Patent Application Publication
(10) Pub. No.: US 2025/0311497 A1
(43) Pub. Date: Oct. 2, 2025

(54) ARC DISPLAY DEVICE

(71) Applicant: AUO Corporation, Hsinchu City (TW)

(72) Inventors: Yea-Ching CHEN, Hsinchu City (TW); Li-Yuan Liao, Hsinchu City (TW); Teng-Yuan Kuo, Hsinchu City (TW); Ching-Fu Tien, Hsinchu City (TW)

(21) Appl. No.: 18/923,760

(22) Filed: Oct. 23, 2024

(30) Foreign Application Priority Data
Mar. 28, 2024 (TW) 113111880

(51) Int. Cl. H01L 27/15

(52) U.S. Cl. CPC H10H 29/142

(57) ABSTRACT

An arc display device includes non-rectangular substrates and pixels disposed on each non-rectangular substrate. The pixels are arranged into columns and rows. Each non-rectangular substrate has a first side, a second side connected to the first side, and a third side opposite to the first side. The columns include a first edge column and a second edge column adjacent to the first side and the third side, respectively. The rows include a first edge row adjacent to the second side. The first distances from the pixels in the first edge column to the first side are equal, the second distances from the pixels in the second edge column to the third side are equal, and the third distances from the pixels in the first edge row to the second side are equal. The first distances are equal to the second distances.

### CROSS-REFERENCE TO RELATED APPLICATION

This application claims priority to Taiwan Application Ser. No. 113111880, filed Mar. 28, 2024, which is herein incorporated by reference in its entirety.

### BACKGROUND

### Field of Invention

The present disclosure relates to an arc display device. More particularly, the present disclosure relates to an arc display device including multiple non-rectangular substrates.

### Description of Related Art

With the development of the technology industry, display devices have been widely used in daily life. By splicing multiple display units (light panels) including light emitting elements on a curved surface, arc displays provide a different experience from flat displays and are often used in large-size exhibitions. Since the display surface of an arc display device is non-planar, the shape of the light panel may be non-rectangular and polygonal with beveled edges. In the case of a spherical display device, for example, the shape of the light panel close to the equator may be trapezoidal, and the shape of the light panel close to the north pole and the south pole may be a special-shaped panel with more than five edges.

However, if the light emitting elements are arranged on a non-rectangular light panel with beveled edges in the same manner as they are generally arranged on a rectangular light panel, the distance from the light emitting elements located adjacent to the beveled edge of the light panel to the beveled edge of the light panel will be different, thereby resulting in the occurrence of bright or dark lines at the splicing joints, which in turn affect the display quality.

### SUMMARY

At least one embodiment of the present disclosure provides an arc display device that can reduce the occurrence of bright or dark lines at splicing points, thereby maintaining or improving display quality.

The arc display device according to at least one embodiment of the present disclosure includes multiple non-rectangular substrates and multiple pixel arrays. Each of the non-rectangular substrates has a first side, a second side connected to the first side, and a third side opposite to the first side. The pixel arrays are disposed on the non-rectangular substrates, respectively. Each of the pixel arrays includes multiple light emitting pixels arranged into multiple pixel rows and multiple pixel columns, the pixel columns include a first edge pixel column adjacent to the first side and a second edge pixel column adjacent to the third side, and the pixel rows include a first edge pixel row adjacent to the second side. The distances from the light emitting pixels in the first edge pixel column to the first side are the same, the distances from the light emitting pixels in the first edge pixel row to the second side are the same, and the distances from the light emitting pixels in the second edge pixel column to the third side are the same.

The distances from the light emitting pixels in the first edge pixel column to the first side are equal to the distances from the light emitting pixels in the second edge pixel column to the third side.

The arc display device according to at least another embodiment of the present disclosure includes multiple non-rectangular substrates and multiple pixel arrays. Each of the non-rectangular substrates has a first side, a second side connected to the first side, and a third side opposite to the first side. The pixel arrays are disposed on the non-rectangular substrates, respectively. Each of the pixel arrays includes multiple light emitting pixels arranged into multiple pixel rows and multiple pixel columns, the pixel columns include a first edge pixel column adjacent to the first side and a second edge pixel column adjacent to the third side, and the pixel rows include a first edge pixel row adjacent to the second side. The distances from the light emitting pixels in the first edge pixel column to the first side are the same, the distances from the light emitting pixels in the first edge pixel row to the second side are the same, and the distances from the light emitting pixels in the second edge pixel column to the third side are the same. The non-rectangular substrates include two adjacent non-rectangular substrates, and the third side of one of the two adjacent non-rectangular substrates is spliced to the first side of the other of the two adjacent non-rectangular substrates. An included angle is existed between normal lines of the two adjacent non-rectangular substrates, a spacing is existed between the light emitting pixels in the second edge pixel column of the one of the two adjacent non-rectangular substrates and the light emitting pixels in the first edge pixel column of the other of the two adjacent non-rectangular substrates, a distance is existed between the light emitting pixels in the second edge pixel column of the one of the two adjacent non-rectangular substrates and the third side of the one of the two adjacent non-rectangular substrates, and each of the light emitting pixels in the second edge pixel column of the one of the two adjacent non-rectangular substrates has a height. The distance, the spacing, half of the included angle, and the height satisfy the following mathematical equation:

$$L 1 = ( \frac{d 1}{2 sin θ 1} + h 1 ) \times tan θ 1 ,$$

where L1 is the distance, d1 is the spacing, θ1 is half of the included angle, and h1 is the height.

### BRIEF DESCRIPTION OF THE DRAWINGS

FIG. 1 is a schematic view of an arc display device according to at least one embodiment of the present disclosure.

FIG. 2 is a partial enlarged schematic view of an arc display screen in FIG. 1A.

FIG. 3A is an enlarged view of region A in FIG. 2.

FIG. 3B is a schematic view of a display unit in FIG. 3A.

FIG. 3C is a schematic view of a display unit according to at least another embodiment of the present disclosure.

FIG. 4A is an enlarged view of region B in FIG. 2.

FIG. 4B is a schematic view of a display unit in FIG. 4A.

FIG. 4C is a schematic view of a display unit according to at least another embodiment of the present disclosure.

FIG. 5A is a schematic top view of two adjacent non-rectangular substrates in FIG. 3A and FIG. 4A.

FIG. 5B is a schematic side view of two adjacent non-rectangular substrates in FIG. 3A and FIG. 4A.

### DETAILED DESCRIPTION

In the following description, in order to clearly present the technical features of the present disclosure, the dimensions (such as length, width, thickness, and depth) of elements (such as layers, films, substrates, and areas) in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case are mainly for illustration, and are not intended to accurately depict the actual shape of the elements, nor are they intended to limit the scope of patent applications in this case.

Furthermore, the words “about”, “approximately” or “substantially” used in the present disclosure not only cover the clearly stated numerical values and numerical ranges, but also cover those that can be understood by a person with ordinary knowledge in the technical field to which the present disclosure belongs. The permissible deviation range can be determined by the error generated during measurement, and the error is caused, for example, by limitations of the measurement system or process conditions. For example, two objects (such as the plane or traces of a substrate) are “substantially parallel” or “substantially perpendicular,” where “substantially parallel” and “substantially perpendicular,” respectively, mean that parallelism and perpendicularity between the two objects can include non-parallelism and non-perpendicularity caused by permissible deviation ranges.

In addition, “about” may mean within one or more standard deviations of the above values, such as within +30%, +20%, +10%, or +5%. Such words as “about”, “approximately”, or “substantially” as appearing in the present disclosure may be used to select an acceptable range of deviation or standard deviation according to optical properties, etching properties, mechanical properties, or other properties, rather than applying all of the above optical properties, etching properties, mechanical properties, and other properties with a single standard deviation.

The spatial relative terms used in the present disclosure, such as “below,” “under,” “above,” “on,” and the like, are intended to facilitate the recitation of a relative relationship between one element or feature and another as depicted in the drawings. The true meaning of these spatial relative terms includes other orientations. For example, the relationship between one element and another may change from “below” and “under” to “above” and “on” when the drawing is turned 180 degrees up or down. In addition, spatially relative descriptions used in the present disclosure should be interpreted in the same manner.

It should be understood that while the present disclosure may use terms such as “first”, “second”, “third” to describe various elements or features, these elements or features should not be limited by these terms. These terms are primarily used to distinguish one element from another, or one feature from another. In addition, the term “or” as used in the present disclosure may include, as appropriate, any one or a combination of the listed items in association.

Moreover, the present disclosure may be implemented or applied in various other specific embodiments, and the details of the present disclosure may be combined, modified, and altered in various embodiments based on different viewpoints and applications, without departing from the idea of the present disclosure.

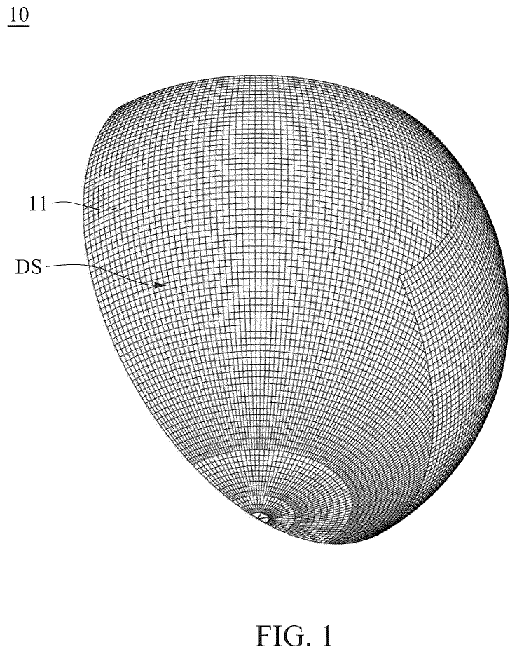

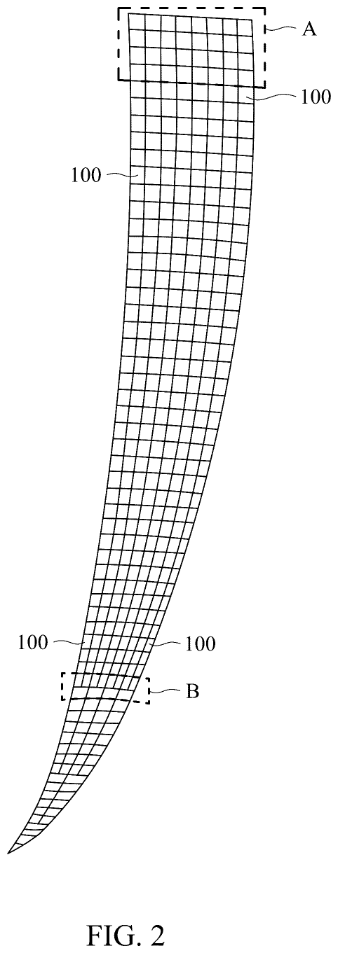

FIG. 1 is a schematic view of an arc display device 10 according to at least one embodiment of the present disclosure. FIG. 2 is a partial enlarged schematic view of an arc display screen 11 in FIG. 1A. Referring to FIG. 1 and FIG. 2, the arc display device 10 includes an arc display screen 11. The arc display screen 11 has a display surface DS, which is the concave curved surface of the arc display device 10. The arc display screen 11 includes multiple display units 100.

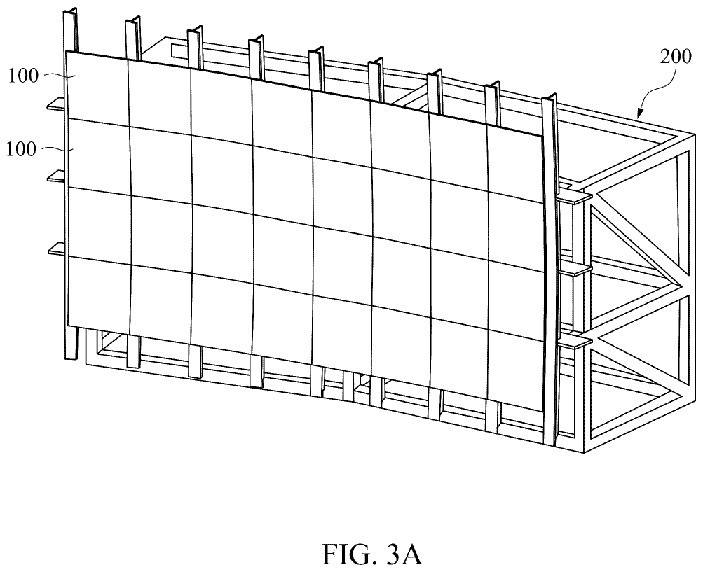

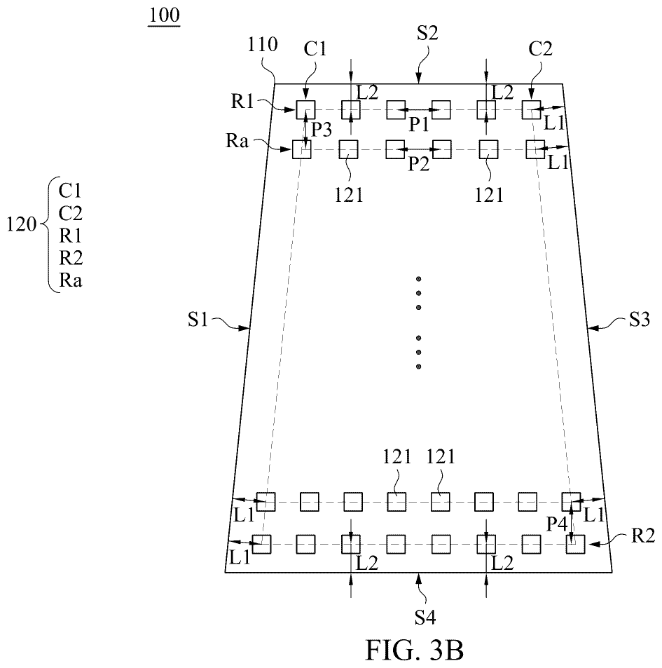

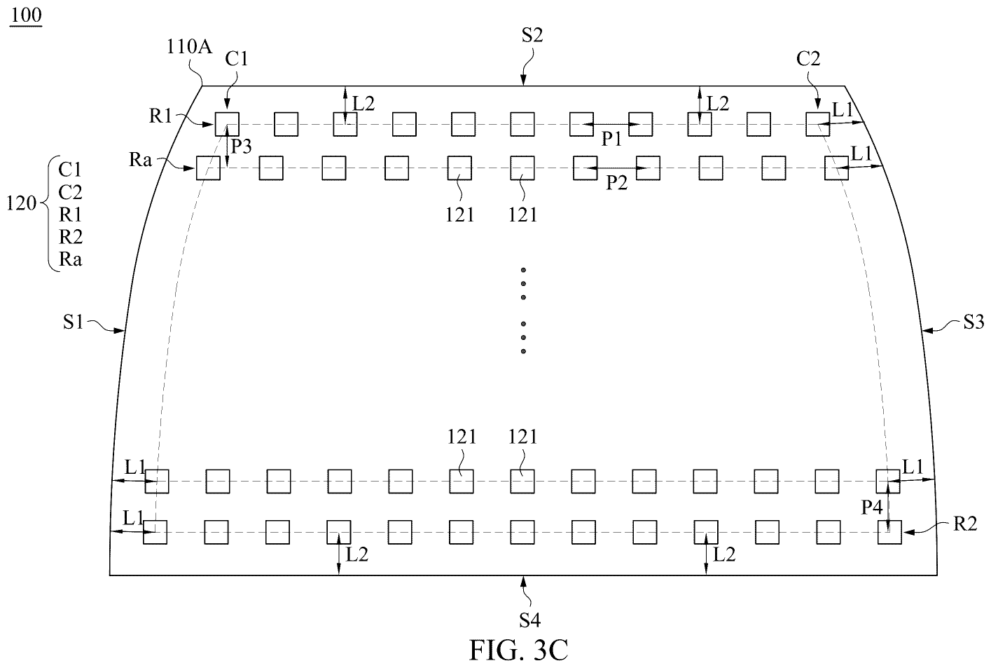

FIG. 3A is an enlarged view of region A in FIG. 2. Referring to FIG. 3A, the arc display screen 11 further includes a bracket 200, and the display units 100 are spliced and disposed on the bracket 200.

FIG. 3B is a schematic view of a display unit 100 in FIG. 3A. Referring to FIG. 3B, the display unit 100 includes a non-rectangular substrate 110 and a pixel array 120 disposed on the non-rectangular substrate 110. Since the arc display device 10 includes multiple display units 100, the arc display device 10 includes multiple non-rectangular substrates 110 and multiple pixel arrays 120 disposed on the non-rectangular substrates 110, respectively.

As shown in FIG. 3B, the non-rectangular substrate 110 has a first side S1, a second side S2 connected to the first side S1, and a third side S3 opposite to the first side S1. The pixel array 120 includes multiple light emitting pixels 121 arranged into multiple pixel rows and multiple pixel columns. The pixel columns include a first edge pixel column C1 adjacent to the first side S1 and a second edge pixel column C2 adjacent to the third side S3, and the pixel rows include the first edge pixel row R1 adjacent to the second side S2.

The distances L1 from the light emitting pixels 121 in the first edge pixel column C1 to the first side S1 are the same. The distances L1 from the light emitting pixels 121 in the second edge pixel column C2 to the third side S3 are the same. The distances L2 from the light emitting pixels 121 in the first edge pixel row R1 to the second side S2 are the same. The distances L1 from the light emitting pixels 121 in the first edge pixel column C1 to the first side S1 are equal to the distances L1 from the light emitting pixels 121 in the second edge pixel column C2 to the third side S3.

Through the above-mentioned design, two adjacent non-rectangular substrates are spliced in the arc display device, the distances from the light emitting pixels in the edge pixel column adjacent to the spliced edge of one of the two adjacent non-rectangular substrates to the light emitting pixels in the edge pixel column adjacent to the spliced edge of the other of the two adjacent non-rectangular substrates are the same, so as to reduce the occurrence of bright or dark lines at splicing points, and thus to maintain or improve the display quality.

For example, the first side S1 of the non-rectangular substrate 110 is spliced to the third side S3 of another non-rectangular substrate 110, the distances L1 between the light emitting pixels 121 in the first edge pixel column C1 adjacent to the first side S1 and the first side S1 are the same, and the distances L1 between the light emitting pixels 121 in the second edge pixel column C2 adjacent to the third side S3 and the third side S3 are the same. Therefore, the distances between the light emitting pixels 121 in the first edge pixel column C1 adjacent to the first side S1 of the non-rectangular substrate 110 and the light emitting pixels 121 in the second edge pixel column C2 adjacent to the third side S3 of another non-rectangular substrate 110 are also the same, thereby reducing the occurrence of bright or dark lines at splicing points, and maintaining or improving the display quality.

Referring to FIG. 3B, the non-rectangular substrate 110 further has a fourth side S4 connected to the first side S1. The pixel rows further include a second edge pixel row R2 adjacent to the fourth side S4. The distances L2 from the light emitting pixels 121 in the second edge pixel row R2 to the fourth side S4 are the same, and the distances L2 from the light emitting pixels 121 in the second edge pixel row R2 to the fourth side S4 are equal to the distances L2 from the light emitting pixels 121 in the first edge pixel row R1 to the second side S2.

Through the above-mentioned design, two adjacent non-rectangular substrates are spliced in the arc display device, the distances from the light emitting pixels in the edge pixel row adjacent to the spliced edge of one of the two adjacent non-rectangular substrates to the light emitting pixels in the edge pixel row adjacent to the spliced edge of the other of the two adjacent non-rectangular substrates are the same, so as to reduce the occurrence of bright or dark lines at splicing points, and thus to maintain or improve the display quality.

For example, the second side S2 of the non-rectangular substrate 110 is spliced to the fourth side S4 of another non-rectangular substrate 110, the distances L2 between the light emitting pixels 121 in the first edge pixel row R1 adjacent to the second side S2 and the second side S2 are the same, and the distances L2 between the light emitting pixels 121 in the second edge pixel row R2 adjacent to the fourth side S4 and the fourth side S4 are the same. Therefore, the distances between the light emitting pixels 121 in the first edge pixel row R1 adjacent to the second side S2 of the non-rectangular substrate 110 and the light emitting pixels 121 in the second edge pixel row R2 adjacent to the fourth side S4 of another non-rectangular substrate 110 are also the same, thereby reducing the occurrence of bright or dark lines at splicing points, and maintaining or improving the display quality.

In some embodiments, the distances L1 from the light emitting pixels 121 in the first edge pixel column C1 to the first side S1 may be equal to or not equal to the distances L2 from the light emitting pixels 121 in the first edge pixel row R1 to the second side S2. Through the aforementioned design, the cutting angle of the display unit 100 can be flexibly adjusted.

In addition, as shown in FIG. 3B, the pitches P1 between the light emitting pixels 121 in the same pixel row (e.g., the first edge pixel row R1) are the same, and the pitches P3 between the light emitting pixels 121 in the same pixel column (e.g., the first edge pixel column C1) are the same.

The pixel rows include two adjacent pixel rows (e.g., the first edge pixel row R1 and the pixel row Ra adjacent to the first edge pixel row R1). The pitches P1 between the light emitting pixels 121 in one of the two adjacent pixel rows (e.g., the first edge pixel row R1) are not equal to the pitches P2 between the light emitting pixels 121 in the other of two adjacent pixel rows (e.g., the pixel row Ra adjacent to the first edge pixel row R1).

In addition, the pitches P3 between the light emitting pixels 121 in one of any two pixel columns (e.g., the first edge pixel column C1) are equal to the pitches P4 between the light emitting pixels 121 in the other of the any two pixel columns (e.g., the second edge pixel column C2).

As shown in FIG. 3B, the distances L1 from the light emitting pixels 121 in the first edge pixel column C1 to the first side S1 are the shortest distances from the geometric centers of the aforementioned light emitting pixels 121 to the first side S1. In other words, the distances L1 are equal to the shortest distance between a connecting line of the geometric centers of the aforementioned light emitting pixel 121 parallel to the first side S1 (i.e., the dotted line shown in FIG. 3B) and the first side S1.

Similarly, the distances L1 from the light emitting pixels 121 in the second edge pixel column C2 to the third side S3 are the shortest distances from the geometric centers of the aforementioned light emitting pixels 121 to the third side S3. In other words, the distances L1 are equal to the shortest distance between a connecting line of the geometric centers of the aforementioned light emitting pixel 121 parallel to the third side S3 (i.e., the dotted line shown in FIG. 3B) and the third side S3.

The distances L2 from the light emitting pixels 121 in the first edge pixel row R1 to the second side S2 are the shortest distances from the geometric centers of the aforementioned light emitting pixels 121 to the second side S2. In other words, the distances L2 are equal to the shortest distance between a connecting line of the geometric centers of the aforementioned light emitting pixel 121 parallel to the second side S2 (i.e., the dotted line shown in FIG. 3B) and the second side S2. The distances L2 from the light emitting pixels 121 in the second edge pixel row R2 to the fourth side S4 are the shortest distances from the geometric centers of the aforementioned light emitting pixels 121 to the fourth side S4. In other words, the distances L2 are equal to the shortest distance between a connecting line of the geometric centers of the aforementioned light emitting pixel 121 parallel to the fourth side S4 (i.e., the dotted line shown in FIG. 3B) and the fourth side S4.

In addition, as shown in FIG. 3B, the pitch P3 between the light emitting pixels 121 in the same pixel column (e.g., the first edge pixel column C1) is the shortest distance (i.e., the perpendicular distance) between the geometric centers of the two adjacent light emitting pixels 121. The pitch P1 between the light emitting pixels 121 in the same pixel row (e.g., the first edge pixel row R1) is the shortest distance (i.e., the horizontal distance) between the geometric centers of the two adjacent light emitting pixels 121.

In some embodiments, a light emitting pixel 121 may include multiple light emitting elements, for example, three light emitting elements, and the three light emitting elements may include a red light emitting element, a green light emitting element, and a blue light emitting element, but the present disclosure is not limited thereto.

The light emitting element may be a light emitting diode (LED), which is, for example, a sub-millimeter light emitting diode (mini LED) or a micro light emitting diode (micro LED, uLED). In addition, the light emitting element may also be a large-sized regular LED other than a sub-millimeter light emitting diode and a micro light emitting diode, so the light emitting element is not limited to a smaller sub-millimeter light emitting diode or a micro light emitting diode.

Referring to FIG. 3B, the shape of the non-rectangular substrate 110 is a trapezoid. That is, the second side S2 and the fourth side S4 are the upper base and the lower base of the trapezoid parallel to each other, respectively, and the first side S1 and the third side S3 are the two lateral sides of the trapezoid, but the present disclosure is not limited thereto.

FIG. 3C is a schematic view of a display unit 100 according to at least another embodiment of the present disclosure. Referring to FIG. 3C, the structures and the relative positions of most elements in the embodiment of FIG. 3C and the embodiment of FIG. 3B are the same, so the same features are not repeated here. The difference between the embodiment of FIG. 3C and the embodiment of FIG. 3B is that the first side S1 and the third side S3 of the non-rectangular substrate 110A in FIG. 3C are curves.

Therefore, as shown in FIG. 3C, the distances L1 from the light emitting pixels 121 in the first edge pixel column C1 to the first side S1 are the shortest distance between a connecting line of the geometric centers of the aforementioned light emitting pixel 121 with a curvature as the same as the first side S1 (i.e., the dotted line shown in FIG. 3C) and the first side S1.

Similarly, the distances L1 from the light emitting pixels 121 in the second edge pixel column C2 to the third side S3 are the shortest distance between a connecting line of the geometric centers of the aforementioned light emitting pixel 121 with a curvature as the same as the third side S3 (i.e., the dotted line shown in FIG. 3C) and the third side S3.

In addition, the pitch P3 between the light emitting pixels 121 in the same pixel column (e.g., the first edge pixel column C1) is the shortest distance (i.e., the perpendicular distance) between the geometric centers of the two adjacent light emitting pixels 121.

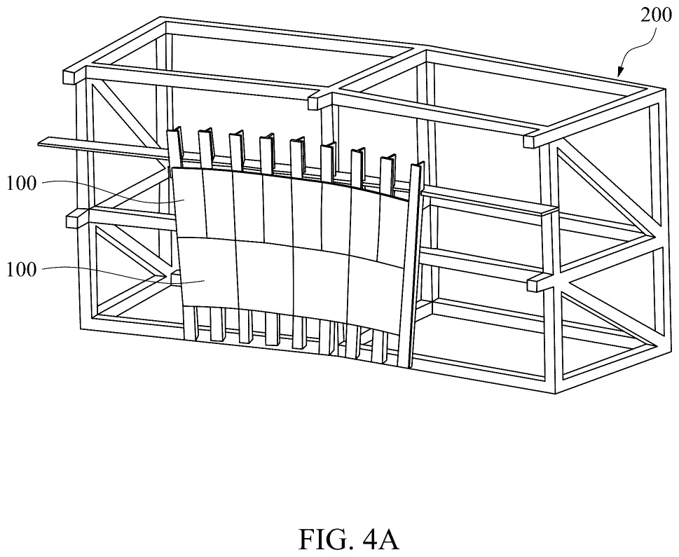

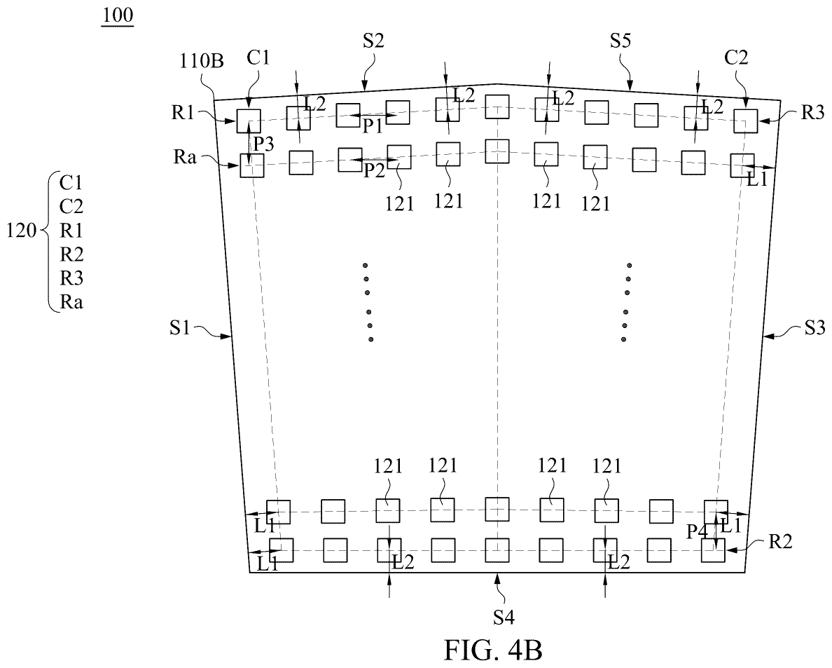

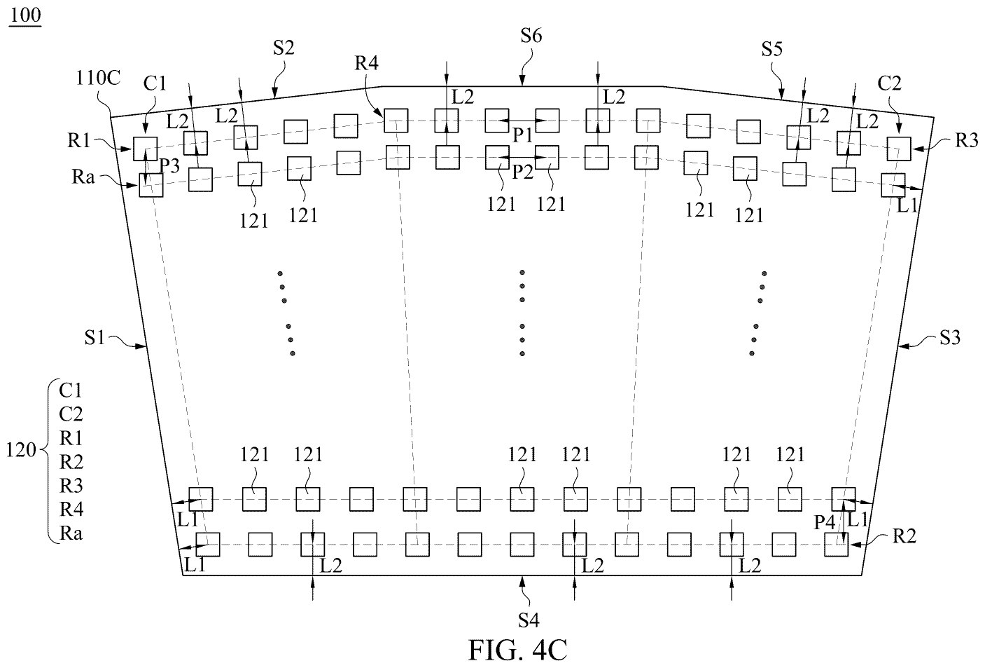

FIG. 4A is an enlarged view of region B in FIG. 2. Referring to FIG. 4A, the display units 100 are spliced and disposed on the bracket 200. In addition, as shown in FIG. 2, the region B is closer to the pole than the region A. Therefore, the display units 100 in FIG. 4A not only include a display unit 100 in trapezoid, but also includes a display unit 100 in pentagon spliced under the display unit 100 in trapezoid.

FIG. 4B is a schematic view of a display unit in FIG. 4A. Referring to FIG. 4B, the structures and the relative positions of most elements in the embodiment of FIG. 4B and the embodiment of FIG. 3B are the same, so the same features are not repeated here. The difference between the embodiment of FIG. 4B and the embodiment of FIG. 3B is that the shape of the non-rectangular substrate 110B in FIG. 4B is a pentagon.

As shown in FIG. 4B, the non-rectangular substrate 110B further has a fifth side S5 connected to the second side S2 and the third side S3. The pixel rows further include a third edge pixel row R3 adjacent to the fifth side S5. The distances L2 from the light emitting pixels 121 in the third edge pixel row R3 to the fifth side S5 are the same, and the distances L2 from the light emitting pixels 121 in the third edge pixel row R3 to the fifth side S5 are equal to the distances L2 from the light emitting pixels 121 in the first edge pixel row R1 to the second side S2.

The distances L2 from the light emitting pixels 121 in the third edge pixel row R3 to the fifth side S5 are the shortest distances from the geometric centers of the aforementioned light emitting pixels 121 to the fifth side S5. In other words, the distances L2 are equal to the shortest distance between a connecting line of the geometric centers of the aforementioned light emitting pixels 121 parallel to the fifth side S5 (i.e., the dotted line shown in FIG. 3B) and the fifth side S5.

In some embodiments, the angle between the fifth side S5 and the second side S2 is greater than 90 degrees and less than 180 degrees. That is, the angle between the connecting line of the geometric centers of the light emitting pixels 121 in the third edge pixel row R3 parallel to the fifth side S5 and the connecting line of the geometric centers of the light emitting pixels 121 in the first edge pixel row R1 parallel to the second side S2 is also greater than 90 degrees and less than 180 degrees.

In addition, the pitches between the light emitting pixels 121 in one of two pixel columns are not equal to the pitches between the light emitting pixels 121 in the other of the two pixel columns.

FIG. 4C is a schematic view of a display unit 100 according to at least another embodiment of the present disclosure. Referring to FIG. 4C, the structures and the relative positions of most elements in the embodiment of FIG. 4C and the embodiment of FIG. 3B are the same, so the same features are not repeated here. The difference between the embodiment of FIG. 4C and the embodiment of FIG. 3B is that the shape of the non-rectangular substrate 110C in FIG. 4C is a hexagon. That is, the display units 100 in FIG. 4A not only include a display unit 100 in trapezoid, but also includes a display unit 100 in hexagon spliced under the display unit 100 in trapezoid.

As shown in FIG. 4C, the non-rectangular substrate 110C further has a fifth side S5 connected to the third side S3 and a sixth side S6 connected to the second side S2 and the fifth side S5. The pixel rows further include a third edge pixel row R3 adjacent to the fifth side S5 and a fourth edge pixel row R4 adjacent to the sixth side S6. The distances L2 from the light emitting pixels 121 in the third edge pixel row R3 to the fifth side S5 are the same, and the distances L2 from the light emitting pixels 121 in the fourth edge pixel row R4 to the sixth side S6 are the same.

The distances L2 from the light emitting pixels 121 in the third edge pixel row R3 to the fifth side S5 are equal to the distances L2 from the light emitting pixels 121 in the first edge pixel row R1 to the second side S2, and the distances L2 of the light emitting pixels 121 in the fourth edge pixel row R4 to the sixth side S6 are equal to the distances L2 from the light emitting pixels 121 in the third edge pixel row R3 to the fifth side S5.

The distances L2 from the light emitting pixels 121 in the third edge pixel row R3 to the fifth side S5 are the shortest distances from the geometric centers of the aforementioned light emitting pixels 121 to the fifth side S5. In other words, the distances L2 are equal to the shortest distance between a connecting line of the geometric centers of the aforementioned light emitting pixels 121 parallel to the fifth side S5 (i.e., the dotted line shown in FIG. 4C) and the fifth side S5.

The distances L2 from the light emitting pixels 121 in the fourth edge pixel row R4 to the sixth side S6 are the shortest distances from the geometric centers of the aforementioned light emitting pixels 121 to the sixth side S6. In other words, the distances L2 are equal to the shortest distance between a connecting line of the geometric centers of the aforementioned light emitting pixels 121 parallel to the sixth side S6 (i.e., the dotted line shown in FIG. 4C) and the sixth side S6.

In some embodiments, the angle between the sixth side S6 and the second side S2 is greater than 90 degrees and less than 180 degrees, and the angle between the fifth side S5 and the sixth side S6 and is greater than 90 degrees and less than 180 degrees.

That is, the angle between the connecting line of the geometric centers to each other of the light emitting pixels 121 in the fourth edge pixel row R4 parallel to the sixth side S6 and the connecting line of the geometric centers of the light emitting pixels 121 in the first edge pixel row R1 parallel to the second side S2 is also greater than 90 degrees and less than 180 degrees, and the angle between the connecting line of the geometric centers of the light emitting pixels 121 in the third edge pixel row R3 parallel to the fifth side S5 and the connecting line of the geometric centers of the light emitting pixels 121 in the fourth edge pixel row R4 parallel to the sixth side S6 is also greater than 90 degrees and less than 180 degrees.

In addition, the pitches between the light emitting pixels 121 in one of two pixel columns are not equal to the pitches between the light emitting pixels 121 in the other of the two pixel columns.

Referring to FIG. 3B and FIG. 4A to FIG. 4C, the second side S2 and the fifth side S5 of the non-rectangular substrate 110B of FIG. 4B can be spliced to the second sides S2 of two non-rectangular substrates 110 of FIG. 3B, respectively. The second side S2, the fifth side S5, and the sixth side S6 of the non-rectangular substrate 110C of FIG. 4C can be spliced to the second sides S2 of three non-rectangular substrates 110 of FIG. 3B, respectively. In some embodiments, the non-rectangular substrate 110B in pentagon has a cutting angle that is twice of a cutting angle of the non-rectangular substrate 110 in trapezoid, and the non-rectangular substrate 110C in hexagon has a cutting angle that is three times of the cutting angle of the non-rectangular substrate 110 in trapezoid.

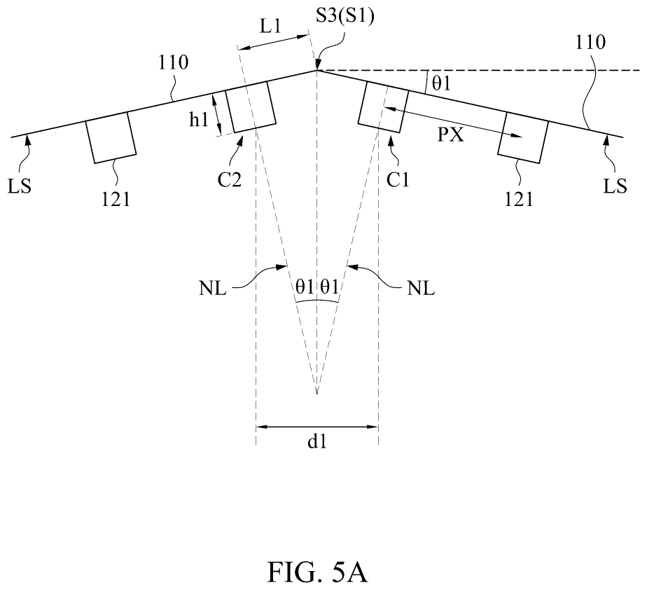

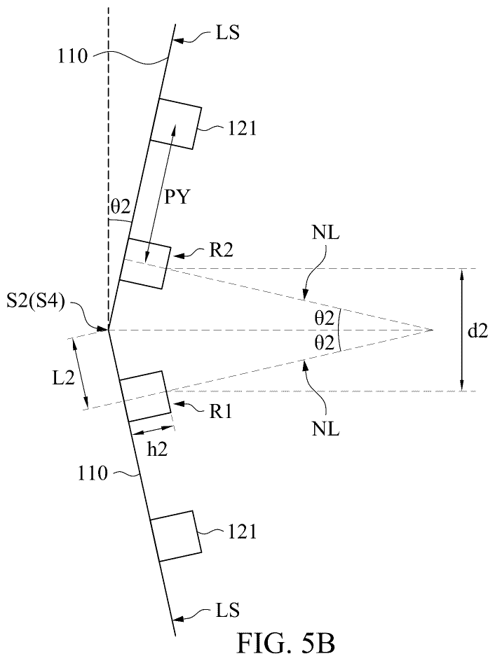

FIG. 5A is a schematic top view of two adjacent non-rectangular substrates in FIG. 3A and FIG. 4A. For illustrative purposes, FIG. 5A merely shows the non-rectangular substrate 110 and the light emitting pixels 121. Referring to FIG. 5A, the third side S3 of one of the two adjacent non-rectangular substrates 110 is spliced to the first side S1 of the other of the two adjacent non-rectangular substrates 110.

There is an included angle between the normal lines NL of two adjacent non-rectangular substrates 110, that is, there is an included angle between the normal lines NL of the surfaces LS of the two adjacent non-rectangular substrates 110 for disposing the light emitting pixels 121. There is a spacing d1 between the light emitting pixels 121 in the second edge pixel column C2 of one of the two adjacent non-rectangular substrates 110 and the light emitting pixels 121 in the first edge pixel column C1 of the other of the two adjacent non-rectangular substrates 110. There is a distance L1 from the light emitting pixels 121 in the second edge pixel column C2 of one of the two adjacent non-rectangular substrates 110 to the third side S3 of the one of the two adjacent non-rectangular substrates 110. Each of the light emitting pixels 121 in the second edge pixel column C2 of one of the two adjacent non-rectangular substrates 110 has a height h1.

As shown in FIG. 5A, the distance L1, the spacing d1, the half angle θ1 of the included angle, and the height h1 satisfy the following mathematical equation (1). The following mathematical equation (1) can be derived from geometric mathematics.

$$L 1 = ( \frac{d 1}{2 sin θ 1} + h 1 ) \times tan θ 1 \qquad ( 1 )$$

The half angle θ1 of the included angle between the normal lines NL of two adjacent non-rectangular substrates 110 is also equal to the included angle between one of the two adjacent non-rectangular substrates 110 and the plane parallel to the connecting direction of the poles of the arc display screen 11 in FIG. 1 (i.e., the thick dotted line shown in FIG. 5A), i.e., the included angle between one of the two adjacent non-rectangular substrates 110 and the vertical plane (i.e., the thick dotted line shown in FIG. 5A) of the arc display screen 11 in FIG. 1.

In addition, the spacing d1 between the light emitting pixels 121 in the second edge pixel column C2 of one of the two adjacent non-rectangular substrates 110 and the light emitting pixels 121 in the first edge pixel column C1 of the other of the two adjacent non-rectangular substrates 110 is the shortest distance from the surface (e.g., light emitting surface) of the light emitting pixel 121 in the aforementioned second edge pixel column C2 to the surface (e.g., light emitting surface) of the light emitting pixel 121 in the aforementioned first edge pixel column C1.

In some embodiments, the spacing d1 between the light emitting pixels 121 in the second edge pixel column C2 of one of the two adjacent non-rectangular substrates 110 and the light emitting pixels 121 in the first edge pixel column C1 of the other of the two adjacent non-rectangular substrates 110 is less than or equal to the pitch PX between the light emitting pixels 121 of each pixel row on two adjacent non-rectangular substrates 110.

FIG. 5B is a schematic side view of two adjacent non-rectangular substrates in FIG. 3A and FIG. 4A. For illustrative purposes, FIG. 5B merely shows the non-rectangular substrate 110 and the light emitting pixels 121. Referring to FIG. 5B, the second side S2 of one of the two adjacent non-rectangular substrates 110 is spliced to the fourth side S4 of the other of the two adjacent non-rectangular substrates 110.

There is an included angle between the normal lines NL of two adjacent non-rectangular substrates 110, that is, there is an included angle between the normal lines NL of the surfaces LS of the two adjacent non-rectangular substrates 110 for disposing the light emitting pixels 121. There is a spacing d2 between the light emitting pixels 121 in the first edge pixel row R1 of one of the two adjacent non-rectangular substrates 110 and the light emitting pixels 121 in the second edge pixel row R2 of the other of the two adjacent non-rectangular substrates 110. There is a distance L2 from the light emitting pixels 121 in the first edge pixel row R1 of one of the two adjacent non-rectangular substrates 110 to the second side S2 of the one of the two adjacent non-rectangular substrates 110. Each of the light emitting pixels 121 in the first edge pixel row R1 of one of the two adjacent non-rectangular substrates 110 has a height h2.

As shown in FIG. 5B, the distance L2, the spacing d2, the half angle θ2 of the included angle, and the height h2 satisfy the following mathematical equation (2). The following mathematical equation (2) can be derived from geometric mathematics.

$$L 2 = ( \frac{d 2}{2 sin θ 2} + h 2 ) \times tan θ 2 \qquad ( 2 )$$

The half angle θ2 of the included angle between the normal lines NL of two adjacent non-rectangular substrates 110 is also equal to the included angle between one of the two adjacent non-rectangular substrates 110 and the plane parallel to the connecting direction of the poles of the arc display screen 11 in FIG. 1 (i.e., the thick dotted line shown in FIG. 5B), i.e., the included angle between one of the two adjacent non-rectangular substrates 110 and the vertical plane (i.e., the thick dotted line shown in FIG. 5B) of the arc display screen 11 in FIG. 1.

In addition, the spacing d2 between the light emitting pixels 121 in the first edge pixel row R1 of one of the two adjacent non-rectangular substrates 110 and the light emitting pixels 121 in the second edge pixel row R2 of the other of the two adjacent non-rectangular substrates 110 is the shortest distance from the surface (e.g., light emitting surface) of the light emitting pixel 121 in the aforementioned first edge pixel row R1 to the surface (e.g., light emitting surface) of the light emitting pixel 121 in the aforementioned second edge pixel row R2.

In some embodiments, the spacing d2 between the light emitting pixels 121 in the first edge pixel row R1 of one of the two adjacent non-rectangular substrates 110 and the light emitting pixels 121 in the second edge pixel row R2 of the other of the two adjacent non-rectangular substrates 110 is less than or equal to the pitch PY between the light emitting pixels 121 of each pixel column on two adjacent non-rectangular substrates 110.

In summary, in at least one embodiment of the arc display device of the present disclosure, the distances from the light emitting pixels in the edge pixel columns adjacent to the edges of the non-rectangular substrate to the aforementioned edges are the same, and/or the distances from the light emitting pixels in the edge pixel rows adjacent to the edges of the non-rectangular substrate to the aforementioned edges are the same, when two adjacent non-rectangular substrates are spliced, the distances from the light emitting pixels in the edge pixel column adjacent to the spliced edge of one of the two adjacent non-rectangular substrates to the light emitting pixels in the edge pixel column adjacent to the spliced edge of the other of the two adjacent non-rectangular substrates are the same, and/or the distances from the light emitting pixels in the edge pixel row adjacent to the spliced edge of one of the two adjacent non-rectangular substrates to the light emitting pixels in the edge pixel row adjacent to the spliced edge of the other of the two adjacent non-rectangular substrates are the same, so as to reduce the occurrence of bright or dark lines at splicing points, and thus to maintain or improve the display quality.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

What is claimed is:

1. An arc display device, comprising:
a plurality of non-rectangular substrates, each of the non-rectangular substrates has a first side, a second side connected to the first side, and a third side opposite to the first side; and
a plurality of pixel arrays, disposed on the non-rectangular substrates, respectively, wherein each of the pixel arrays comprises a plurality of light emitting pixels arranged into a plurality of pixel rows and a plurality of pixel columns, the pixel columns comprise a first edge pixel column adjacent to the first side and a second edge pixel column adjacent to the third side, and the pixel rows comprise a first edge pixel row adjacent to the second side,
wherein distances from the light emitting pixels in the first edge pixel column to the first side are the same, distances from the light emitting pixels in the first edge pixel row to the second side are the same, and distances from the light emitting pixels in the second edge pixel column to the third side are the same,
wherein the distances from the light emitting pixels in the first edge pixel column to the first side are equal to the distances from the light emitting pixels in the second edge pixel column to the third side.

2. The arc display device of claim 1, wherein the distances from the light emitting pixels in the first edge pixel column to the first side are not equal to the distances from the light emitting pixels in the first edge pixel row to the second side.

3. The arc display device of claim 1, wherein the non-rectangular substrates comprises two adjacent non-rectangular substrates, and the third side of one of the two adjacent non-rectangular substrates is spliced to the first side of the other of the two adjacent non-rectangular substrates, wherein a spacing between the light emitting pixels in the second edge pixel column of the one of the two adjacent non-rectangular substrates and the light emitting pixels in the first edge pixel column of the other of the two adjacent non-rectangular substrates is less than or equal to a pitch of the light emitting pixels in each of the pixel rows of the two adjacent non-rectangular substrates.

4. The arc display device of claim 1, wherein the non-rectangular substrates comprises two adjacent non-rectangular substrates, and the third side of one of the two adjacent non-rectangular substrates is spliced to the first side of the other of the two adjacent non-rectangular substrates, wherein an included angle is existed between normal lines of the two adjacent non-rectangular substrates, a spacing is existed between the light emitting pixels in the second edge pixel column of the one of the two adjacent non-rectangular substrates and the light emitting pixels in the first edge pixel column of the other of the two adjacent non-rectangular substrates, a distance is existed between the light emitting pixels in the second edge pixel column of the one of the two adjacent non-rectangular substrates and the third side of the one of the two adjacent non-rectangular substrates, and each of the light emitting pixels in the second edge pixel column of the one of the two adjacent non-rectangular substrates has a height, wherein the distance, the spacing, half of the included angle, and the height satisfy the following mathematical equation:
$$L 1 = ( \frac{d 1}{2 sin θ 1} + h 1 ) \times tan θ 1 ,$$
wherein L1 is the distance, d1 is the spacing, θ1 is half of the included angle, and h1 is the height.

5. The arc display device of claim 1, wherein each of the non-rectangular substrates further has a fourth side connected to the first side, and the pixel rows include a second edge pixel row adjacent to the fourth side, wherein distances from the light emitting pixels in the second edge pixel row to the fourth side are the same, and the distances from the light emitting pixels in the second edge pixel row to the fourth side are equal to the distances from the light emitting pixels in the first edge pixel row to the second side.

6. The arc display device of claim 5, wherein the non-rectangular substrates comprises two adjacent non-rectangular substrates, and the second side of one of the two adjacent non-rectangular substrates is spliced to the fourth side of the other of the two adjacent non-rectangular substrates, wherein a spacing between the light emitting pixels in the first edge pixel row of the one of the two adjacent non-rectangular substrates and the light emitting pixels in the second edge pixel row of the other of the two adjacent non-rectangular substrates is less than or equal to a pitch of the light emitting pixels in each of the pixel columns of the two adjacent non-rectangular substrates.

7. The arc display device of claim 5, wherein the non-rectangular substrates comprises two adjacent non-rectangular substrates, and the second side of one of the two adjacent non-rectangular substrates is spliced to the fourth side of the other of the two adjacent non-rectangular substrates, wherein an included angle is existed between normal lines of the two adjacent non-rectangular substrates, a spacing is existed between the light emitting pixels in the first edge pixel row of the one of the two adjacent non-rectangular substrates and the light emitting pixels in the second edge pixel row of the other of the two adjacent non-rectangular substrates, a distance is existed between the light emitting pixels in the first edge pixel row of the one of the two adjacent non-rectangular substrates and the second side of the one of the two adjacent non-rectangular substrates, and each of the light emitting pixels in the first edge pixel row of the one of the two adjacent non-rectangular substrates has a height, wherein the distance, the spacing, half of the included angle, and the height satisfy the following mathematical equation:
$$L 2 = ( \frac{d 2}{2 sin θ 2} + h 2 ) \times tan θ 2 ,$$
wherein L2 is the distance, d2 is the spacing, θ2 is half of the included angle, and h2 is the height.

8. The arc display device of claim 5, wherein each of the non-rectangular substrates further has a fifth side connected to the second side, and the pixel rows further comprise a third edge pixel row adjacent to the fifth side, wherein distances from the light emitting pixels in the third edge pixel row to the fifth side are the same, and the distances from the light emitting pixels in the third edge pixel row to the fifth side are equal to the distances from the light emitting pixels in the first edge pixel row to the second side.

9. The arc display device of claim 5, wherein each of the non-rectangular substrates further has a fifth side connected to the third side and a sixth side connected to the fifth side, and the pixel rows further comprise a third edge pixel row adjacent to the fifth side and a fourth edge pixel row adjacent to the sixth side, wherein distances from the light emitting pixels in the third edge pixel row to the fifth side are the same, and distances from the light emitting pixels in the fourth edge pixel row to the sixth side are the same, wherein the distances from the light emitting pixels in the third edge pixel row to the fifth side are equal to the distances from the light emitting pixels in the first edge pixel row to the second side, and the distances from the light emitting pixels in the fourth edge pixel row to the sixth side are equal to the distances from the light emitting pixels in the third edge pixel row to the fifth side.

10. The arc display device of claim 1, wherein pitches between the light emitting pixels in the same pixel row are the same.

11. The arc display device of claim 10, wherein the pixel rows comprise two adjacent pixel rows, and pitches between the light emitting pixels in one of the two adjacent pixel rows are not equal to pitches between the light emitting pixels in the other of the two adjacent pixel rows.

12. The arc display device of claim 1, wherein pitches between the light emitting pixels in the same pixel column are the same.

13. The arc display device of claim 12, wherein pitches between the light emitting pixels of one of any two of the pixel columns are equal to pitches between the light emitting pixels of the other of the any two of the pixel columns.

14. An arc display device, comprising:
a plurality of non-rectangular substrates, each of the non-rectangular substrates has a first side, a second side connected to the first side, and a third side opposite to the first side; and
a plurality of pixel arrays, disposed on the non-rectangular substrates, respectively, wherein each of the pixel arrays comprises a plurality of light emitting pixels arranged into a plurality of pixel rows and a plurality of pixel columns, the pixel columns comprise a first edge pixel column adjacent to the first side and a second edge pixel column adjacent to the third side, and the pixel rows comprise a first edge pixel row adjacent to the second side,
wherein distances from the light emitting pixels in the first edge pixel column to the first side are the same, distances from the light emitting pixels in the first edge pixel row to the second side are the same, and distances from the light emitting pixels in the second edge pixel column to the third side are the same,
wherein the non-rectangular substrates comprises two adjacent non-rectangular substrates, and the third side of one of the two adjacent non-rectangular substrates is spliced to the first side of the other of the two adjacent non-rectangular substrates, wherein an included angle is existed between normal lines of the two adjacent non-rectangular substrates, a spacing is existed between the light emitting pixels in the second edge pixel column of the one of the two adjacent non-rectangular substrates and the light emitting pixels in the first edge pixel column of the other of the two adjacent non-rectangular substrates, a distance is existed between the light emitting pixels in the second edge pixel column of the one of the two adjacent non-rectangular substrates and the third side of the one of the two adjacent non-rectangular substrates, and each of the light emitting pixels in the second edge pixel column of the one of the two adjacent non-rectangular substrates has a height, wherein the distance, the spacing, half of the included angle, and the height satisfy the following mathematical equation:
$$L 1 = ( \frac{d 1}{2 sin θ 1} + h 1 ) \times tan θ 1 ,$$
wherein L1 is the distance, d1 is the spacing, θ1 is half of the included angle, and h1 is the height.

15. The arc display device of claim 14, wherein the spacing is less than or equal to a pitch of the light emitting pixels in each of the pixel rows of the two adjacent non-rectangular substrates.
